(19) United States
(12) Patent Application Publication
(10) Pub. No.: US 2026/0371966 A1
(43) Pub. Date: Nov. 19, 2026

(54) RESIST PATTERN FILLING LIQUID AND METHOD FOR MANUFACTURING RESIST PATTERN USING THE SAME

(71) Applicant: Merck Patent GmbH, Darmstadt (DE)

(72) Inventors: Hiroshi YANAGITA, Kakagawa-shi (JP); Kazuma YAMAMOTO, Kakagawa-shi (JP)

(21) Appl. No.: 19/478,332

(22) PCT Filed: Apr. 22, 2024
(86) PCT No.: PCT/EP2024/060854

§ 371 Date: Oct. 24, 2025

(30) Foreign Application Priority Data
Apr. 25, 2023 (JP) 2023-071411

(51) Int. Cl. H10P 50/28; G03F 7/004

(52) U.S. Cl. CPC H10P 50/283; G03F 7/0043

(57) ABSTRACT

To provide a resist pattern filling liquid and a method for manufacturing a resist pattern using the same.

### BACKGROUND OF THE INVENTION

### Technical Field

The present invention relates to a resist pattern filling liquid and a method for manufacturing a resist pattern using the same.

### Background Art

In recent years, needs for high integration of LSI has been increasing, and refining of patterns is required. In order to respond such needs, lithography processes using KrF excimer laser, ArF excimer laser, extreme ultraviolet, X-ray of short wavelength, electron beam or the like have been put to practical use. In order to respond to such refining of resist patterns, also for photosensitive resin compositions to be used as a resist during refining processing, those having high resolution are required. Finer patterns can be formed by exposing with light of short wavelength, but since a finer structure is formed, resist pattern collapse sometimes occurs.

Resist pattern collapse also occurs when the pattern is rinsed with pure water after development. In order to improve the resist pattern collapse, there is also consideration of rinsing with a rinse liquid instead of the conventional pure water. In addition, as a method for suppressing the pattern collapse, there is a method in which a resist film after exposure is developed with a gap filling composition and removed by heating (Patent Document 1).

In addition, following methods exist: a method in which a filling composition is applied to a substrate pattern, a film is formed, and the film is removed by vaporizing (Patent Document 2); a method in which a coating solution is applied to a resist pattern, a coating film is formed on the surface of the resist pattern, and the film is removed (Patent Document 3); and a method in which the resist pattern is reversed (Patent Documents 4 and 5).

### PRIOR ART DOCUMENTS

### Patent Documents

[Patent document 1] WO 2017/207452
[Patent document 2] JP 2022-528609 A
[Patent document 3] WO 2018/074358
[Patent document 4] JP 2022-008804 A
[Patent document 5] WO 2015/129405

### SUMMARY OF THE INVENTION

### Problems to be Solved by the Invention

The present inventors have considered that there are one or more objectives that still require improvement. These include, for example, the followings:

Defects often occur in fine resist patterns; resist pattern collapse occurs in fine resist patterns; when the developer or rinse liquid between resist patterns is removed by spin drying, pattern collapse occurs due to surface tension; resist patterns are difficult to cleanly rinsed; precipitation occurs when the developer is replaced with another material; film thickness reduction occurs during the resist pattern rinsing process; and yield is not good.

### Means for Solving the Problems

The resist pattern filling liquid according to the present invention is one that forms a resist pattern filling film,
the etching rate of the filling film (ER_{F}) by dry etching using an etchant containing oxygen satisfies ER_{F}≥0.5 nm/s, and
the filling liquid is different from a developer which is applied to a resist film after exposure to form a resist pattern.

The method for manufacturing a resist pattern according to the present invention comprises the following steps:
(1) applying the above-mentioned filling liquid between the resist patterns formed above the substrate to form a filling film; and
(2) removing the filling film by dry etching using an etchant containing oxygen.

The method for manufacturing a device according to the present invention comprises the following steps:
forming a resist pattern as mentioned above; and
(3) processing using the resist pattern as a mask.

### Effects of the Invention

Using the resist pattern filling liquid of the present invention, one or more of the following effects are provided:

Occurrence of defects in fine resist patterns can be suppressed; resist pattern collapse in fine resist patterns can be suppressed; resist patterns can be cleanly rinsed; film thickness reduction of resist patterns can be suppressed; heating for removing filling films is not required; the filling film can be easily removed; it is possible to reduce the step for removing the film from the substrate pattern rinsing process; a step of removing the filling film, and dry etching of the substrate using the resist pattern as a mask can be performed at once or in succession; precipitates can be suppressed from being formed by making the filling liquid and the developer mixed; process efficiency can be increased; the original resist pattern can be used as a mask without making the resist pattern reversed; and the time that the developer is present between the resist patterns can be shortened.

### BRIEF DESCRIPTION OF THE DRAWINGS

FIG. 1 is an explanatory drawing of the method for manufacturing a resist pattern according to the present invention.

### DETAILED DESCRIPTION OF THE INVENTION

### Mode for Carrying Out the Invention

Embodiments of the present invention are described in detail as follows.

### DEFINITIONS

Unless otherwise specified in the present specification, the definitions and examples described in this paragraph are followed.

The singular form includes the plural form and “one” or “that” means “at least one”. An element of a concept can be expressed by a plurality of species, and when the amount (for example, mass % or mol %) is described, it means sum of the plurality of species.

“And/or” includes a combination of all elements and also includes single use of the element.

When a numerical range is indicated using “to” or “-”, it includes both endpoints and units thereof are common. For example, 5 to 25 mol % means 5 mol % or more and 25 mol % or less.

The descriptions such as “C_{x-y}”, “Cₓ-C_{y}” and “Cₓ” mean the number of carbons in a molecule or substituent. For example, C₁₋₆ alkyl means an alkyl chain having 1 or more and 6 or less carbons (methyl, ethyl, propyl, butyl, pentyl, hexyl etc.).

When a polymer has a plural types of repeating units, these repeating units copolymerize. This copolymerization may be any of alternating copolymerization, random copolymerization, block copolymerization, graft copolymerization, or a mixture thereof. When a polymer or resin is represented by a structural formula, n, m or the like that is attached next to parentheses indicate the number of repetitions.

Celsius is used as the temperature unit. For example, 20 degrees means 20 degrees Celsius.

The additive refers to a compound itself having a function thereof (for example, in the case of a base generator, a compound itself that generates a base). An embodiment in which the compound is dissolved or dispersed in a solvent and added to a composition is also possible. As one embodiment of the present invention, it is preferable that such a solvent is contained in the composition according to the present invention as the solvent (B) or another component.

### <Resist Pattern Filling Liquid>

The resist pattern filling liquid (hereinafter sometimes referred to as “filling liquid”) according to the present invention is applied to the resist pattern, and, for example, by drying the solvent, to form a resist pattern filling film (hereinafter sometimes referred to as “filling film”). The filling liquid according to the present invention can also be called a filling liquid for forming a resist pattern filling film.

The filling liquid according to the present invention is different from a developer which is applied to a resist film after exposure to form a resist pattern. The filling liquid according to the present invention is preferably applied to the resist pattern after the developer has been applied, and is more preferably used to replace the developer present between the resist patterns. At this time, when the developer and filling liquid are mixed, it is more preferable that absorbance does not increase, turbidity does not increase, or solutes derived from at least any of these do not precipitate.

The resist pattern cleaning solution may or may not be applied between the development and the application of the filling liquid. Examples of the resist pattern cleaning solution include a rinse liquid. It is also possible to replace the developer between the resist patterns with a resist pattern cleaning solution and then replace the cleaning solution with the filling liquid according to the present invention.

It is preferable that the filling liquid according to present invention does not substantially change the film thickness of the resist pattern when applied to the resist pattern.

The film thickness of the resist pattern or resist film (FT_{R}), and the film thickness after applying the filling liquid in contact with and above any of these and removing the filling liquid with the solvent of the filling liquid (FT_{R′}) preferably satisfy the following formula:

(FT_{R}−FT_{R′})/FT_{R}×100=±0 to 10%.
(FT_{R}−FT_{R′})/FT_{R}×100 is more preferably ±0 to 5%, further preferably ±0 to 2%.

The composition of the filling liquid according to the present invention is not particularly limited, but preferably comprises a polymer (A) and a solvent (B).

### (A) Polymer

The filling liquid according to the present invention preferably comprises a polymer (A). The liquid comprises a polymer (A) more preferably selected from the group consisting of vinyl resin, acrylic resin, polystyrene resin, oxazoline resin, polycarbonate resin, novolak resin, epoxy resin, maleic resin and imide resin (further preferably selected from the group consisting of vinyl resin, acrylic resin, polystyrene resin, oxazoline resin, and polycarbonate resin; further more preferably selected from the group consisting of vinyl resin, acrylic resin, and polystyrene resin). Although describing for clarity, the polymer (A) can also include multiple polymer. For example, it is also a preferred embodiment of the present invention that the polymer (A) comprises a combination of the above-mentioned vinyl resin and polystyrene resin.

In a preferred embodiment, the polymer (A) can be synthesized by selecting, for example, 1 to 5 types from the following monomers (more preferably 1 to 3 types; further preferably 1 to 2 types).

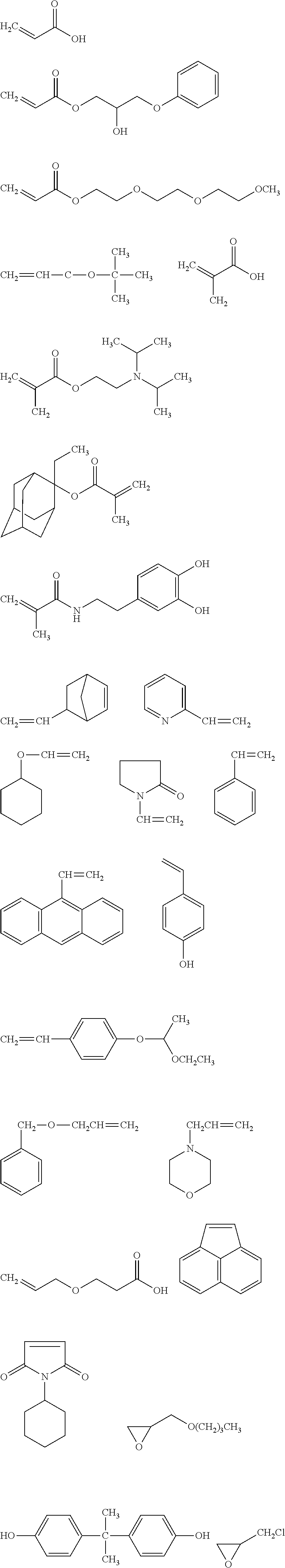

The polymer (A) preferably comprises at least one of the repeating units represented by the formulae (A-1) and (A-2), more preferably comprises the repeating units represented by the formulae (A-1) and (A-2). The polymer (A) can further comprise at least one of the repeating units represented by the formulae (A-3) and (A-4). In one preferred embodiment, the polymer (A) comprises the repeating units represented by the formulae (A-1), (A-2) and (A-3), and more preferably substantially consists of the repeating units represented by the formulae (A-1), (A-2) and (A-3). The formula (A-1) is as follows:

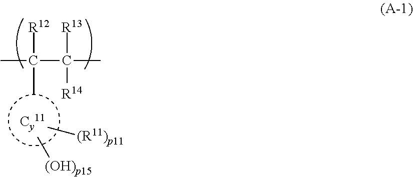

where
C_{y}¹¹ is each independently aryl or heteroaryl having 5 or 6 ring atoms, preferably phenyl.
R¹¹ is each independently C₁₋₅ alkyl (where methylene (—CH₂—) in the alkyl can be replaced with oxy (—O—)), preferably methyl or ethyl, more preferably methyl. In the present invention, the expression “methylene in the alkyl can be replaced with oxy” means that oxy can be present between carbons in the alkyl; however, this is not intended that the terminal carbon in the alkyl becomes oxy, that is, to have alkoxy or hydroxy.
R¹², R¹³ and R¹⁴ are each independently hydrogen, C₁₋₅ alkyl, C₁₋₅ alkoxy or —COOH, preferably hydrogen or methyl, more preferably hydrogen.
p¹¹ is 0 to 4, preferably 0 or 1, more preferably 0.
p¹⁵ is 1 to 2, preferably 1. Provided that p¹¹+p¹⁵≤5 is satisfied.

Exemplified embodiments of the formula (A-1) include the following:

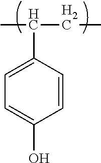

The formula (A-2) is as follows:

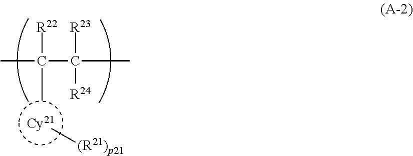

where
Cy²¹ is each independently aryl or heteroaryl having 5 or 6 ring atoms, preferably phenyl.
R²¹ is each independently C₁₋₅ alkyl (where methylene in the alkyl can be replaced with oxy), preferably methyl, ethyl, t-butyl or t-butoxy, more preferably methyl or ethyl, further preferably methyl.
R²², R²³ and R²⁴ are each independently hydrogen, C₁₋₅ alkyl, C₁₋₅ alkoxy or —COOH, preferably hydrogen or methyl, more preferably hydrogen.

p²¹ is 0 to 5, preferably 0, 1, 2, 3, 4 or 5, more preferably 0 or 1, further preferably 0.

Exemplified embodiments of the formula (A-2) include the following:

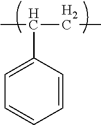

The formula (A-3) is as follows:

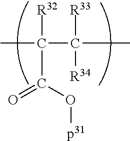

where
R³², R³³ and R³⁴ are each independently hydrogen, C₁₋₅ alkyl, C₁₋₅ alkoxy or —COOH; preferably hydrogen, methyl, ethyl, t-butyl, methoxy, t-butoxy or —COOH; more preferably hydrogen or methyl; further preferably hydrogen.
P³¹ is H or C₄₋₂₀ alkyl. Here, part or all of the alkyl can form a ring, part or all of H in the alkyl can be substituted with halogen, and methylene in the alkyl can be replaced with oxy or carbonyl (—C(═O)—). The alkyl moiety of P³¹ is preferably branched or cyclic. When H in the C₄₋₂₀ alkyl of P³¹ is substituted with halogen, it is preferable that all of them are substituted, and the halogen that substitutes is preferably F or Cl, and more preferably F. It is a preferred embodiment of the present invention that H in the C₄₋₂₀ alkyl of P³¹ is not substituted with halogen. P³¹ is preferably H, methyl, isopropyl, t-butyl, cyclopentyl, methylcyclopentyl, ethylcyclopentyl, cyclohexyl, methylcyclohexyl, ethylcyclohexyl, adamantyl, methyladamantyl or ethyladamantyl (more preferably H, t-butyl, ethylcyclopentyl, ethylcyclohexyl or ethyladamantyl; further preferably H, t-butyl, ethylcyclopentyl or ethyladamantyl; further more preferably t-butyl).

Exemplified embodiments of the formula (A-3) include the following:

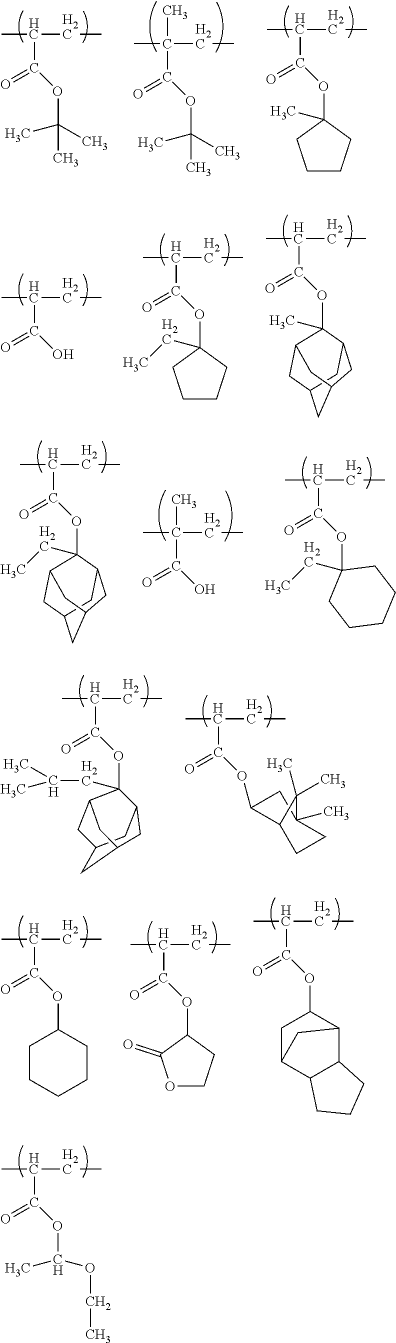

The formula (A-4) is as follows:

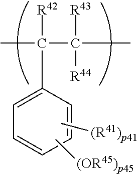

where
R⁴¹ is each independently C₁₋₅ alkyl (where methylene in the alkyl can be replaced with oxy), preferably methyl, ethyl or t-butyl, more preferably methyl.
R⁴⁵ is each independently C₁₋₅ alkyl (where methylene in the alkyl can be replaced with oxy), preferably methyl, t-butyl or —CH(CH₃)—O—CH₂CH₃.
R⁴², R⁴³ and R⁴⁴ are each independently hydrogen, C₁₋₅ alkyl, C₁₋₅ alkoxy or —COOH, preferably hydrogen or methyl, more preferably hydrogen.
p⁴¹ is 0 to 4, more preferably 0 or 1, further preferably 0.
p⁴⁵ is 1 to 2, more preferably 1.
p⁴¹+p⁴⁵≤5 is satisfied.

Exemplified embodiments of the formula (A-4) include the following:

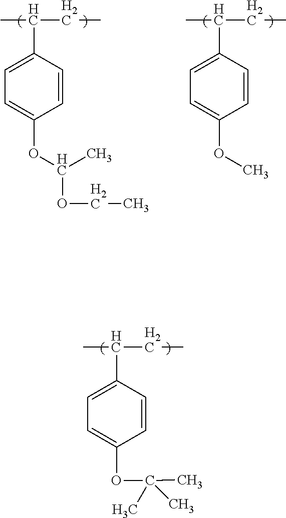

In the polymer (A), numbers of the repeating units n_{A-1}, n_{A-2}, n_{A-3} and nₐ₋₄ of the repeating units (A-1), (A-2), (A-3) and (A-4) are explained below.
n_{A-1}/(n_{A-1}+n_{A-2}+n_{A-3}+n_{A-4}) is preferably 0 to 100%, more preferably 50 to 80%, further preferably 55 to 75%, further more preferably 55% to 65%.
n_{A-2}/(n_{A-1}+n_{A-2}+n_{A-3}+n_{A-4}) is preferably 0 to 100%, more preferably 0 to 30%, further preferably 5 to 25%, further more preferably 15 to 25%.
n_{A-3}/(n_{A-1}+n_{A-2}+n_{A-3}+n_{A-4}) is preferably 0 to 50%, more preferably 10 to 40%, further preferably 15 to 35%, further more preferably 15 to 25%. It is also a preferred embodiment of the present invention that n_{A-3} is 0.
n_{A-4}/(n_{A-1}+n_{A-2}+n_{A-3}+n_{A-4}) is preferably 0 to 50%, more preferably 0 to 30%, further preferably 0 to 10%, further more preferably 0 to 5%. It is also a preferred embodiment of the present invention that n_{A-4} is 0. Preferred embodiments include n_{A-1}/(n_{A-1}+n_{A-2}+n_{A-3}+n_{A-4})=40 to 80%, n_{A-2}/(n_{A-1}+n_{A-2}+n_{A-3}+n_{A-4})=0 to 40%, n_{A-3}/(n_{A-1}+n_{A-2}+n_{A-3}+n_{A-4})=10 to 50%, and n_{A-4}/(n_{A-1}+n_{A-2}+n_{A-3}+n_{A-4})=0 to 40%.

The polymer (A) can also comprise any repeating units other than the repeating units represented by (A-1), (A-2), (A-3) and (A-4). When the total number of all repeating units contained in the polymer (A) is defined to be nₜₒₜₐₗ,
(n_{A-1}+n_{A-2}+n_{A-3}+n_{A-4})/nₜₒₜₐₗ is preferably 80 to 100%, more preferably 90 to 100%, further preferably 95 to 100%. It is also a preferred embodiment of the polymer (A) that it does not contain any further repeating units.

Exemplified embodiments of the polymer (A) include the following:

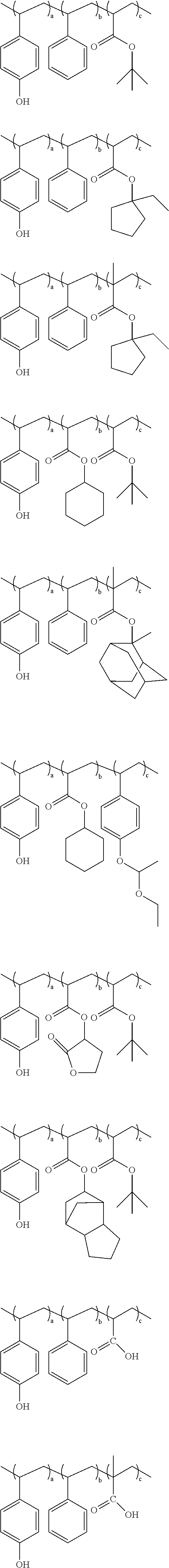

The mass average molecular weight (hereinafter sometimes referred to as Mw) of the polymer (A) is preferably 2,000 to 100,000, more preferably 4,000 to 80,000, further preferably 6,000 to 60,000, further more preferably 8,000 to 40,000.

In the present invention, Mw can be measured by the gel permeation chromatography (GPC). In this measurement, a suitable example is to use a GPC column at 40 degrees Celsius, an elute solvent of tetrahydrofuran at 0.6 mL/min, and monodisperse polystyrene as a standard.

The content of the polymer (A) is preferably 0.05 to 50 mass % (more preferably 0.1 to 10 mass %; further preferably 0.1 to 5 mass %; further more preferably 0.2 to 2 mass %) based on the total mass of the filling liquid.

Although the composition according to the present invention can contain any polymer other than the polymer (A), it is a preferred embodiment that the composition does not contain any polymer other than the polymer (A).

### (B) Solvent

The filling liquid according to the present invention preferably comprises a solvent (B). The solvent (B) is water, a hydrocarbon solvent, an ether solvent, an ester solvent, an alcohol solvent, a ketone solvent, or any combination of any of these.

Exemplified embodiments of the solvent include water, n-pentane, i-pentane, n-hexane, i-hexane, n-heptane, i-heptane, 2,2,4-trimethylpentane, n-octane, i-octane, cyclohexane, methylcyclohexane, benzene, toluene, xylene, ethylbenzene, trimethylbenzene, methylethylbenzene, n-propylbenzene, i-propylbenzene, diethylbenzene, i-butylbenzene, triethylbenzene, di-i-propylbenzene, n-amylnaphthalene, trimethylbenzene, methanol, ethanol, n-propanol, i-propanol, n-butanol, i-butanol, sec-butanol, t-butanol, n-pentanol, i-pentanol, 2-methylbutanol, sec-pentanol, t-pentanol, 3-methoxybutanol, n-hexanol, 2-methylpentanol, sec-hexanol, 2-ethylbutanol, sec-heptanol, heptanol-3, n-octanol, 2-ethylhexanol, sec-octanol, n-nonyl alcohol, 2,6-dimethylheptanol-4, n-decanol, sec-undecyl alcohol, trimethyl nonyl alcohol, sec-tetradecyl alcohol, sec-heptadecyl alcohol, phenol, cyclohexanol, methylcyclohexanol, 3,3,5-trimethylcyclohexanol, benzyl alcohol, phenylmethyl carbinol, diacetone alcohol, cresol, ethylene glycol, propylene glycol, 1,3-butylene glycol, pentanediol-2,4, 2-methylpentanediol-2,4, hexanediol-2,5, heptanediol-2,4, 2-ethylhexanediol-1,3, diethylene glycol, dipropylene glycol, triethylene glycol, tripropylene glycol, glycerin, acetone, methyl ethyl ketone, methyl n-propyl ketone, methyl n-butyl ketone, diethyl ketone, methyl i-butyl ketone, 2-heptanone, ethyl-n-butyl ketone, methyl-n-hexyl ketone, di-i-butyl ketone, trimethyl nonanone, cyclohexanone, cyclopentanone, methylcyclohexanone, 2,4-pentanedione, acetonylacetone, diacetone alcohol, acetophenone, fenchone, ethyl ether, i-propyl ether, n-butyl ether (di-n-butyl ether, DBE), n-hexyl ether, 2-ethylhexyl ether, ethylene oxide, 1,2-propylene oxide, dioxolane, 4-methyl dioxolane, dioxane, dimethyl dioxane, ethylene glycol monomethyl ether, ethylene glycol monoethyl ether, ethylene glycol diethyl ether, ethylene glycol mono-n-butyl ether, ethylene glycol mono-n-hexyl ether, ethylene glycol monophenyl ether, ethylene glycol mono-2-ethyl butyl ether, ethylene glycol dibutyl ether, diethylene glycol monomethyl ether, diethylene glycol monoethyl ether, diethylene glycol mono-n-butyl ether, diethylene glycol di-n-butyl ether, diethylene glycol mono-n-hexyl ether, ethoxytriglycol, tetraethylene glycol di-n-butyl ether, propylene glycol monomethyl ether (PGME), propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, dipropylene glycol monobutyl ether, tripropylene glycol monomethyl ether, tetrahydrofuran, 2-methyltetrahydrofuran, diethyl carbonate, methyl acetate, ethyl acetate, γ-butyrolactone, γ-valerolactone, n-propyl acetate, i-propyl acetate, n-butyl acetate (normal butyl acetate, nBA), i-butyl acetate, sec-butyl acetate, n-pentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methyl cyclohexyl acetate, n-nonyl acetate, methyl acetoacetate, ethyl acetoacetate, ethylene glycol monomethyl ether acetate, ethylene glycol monoethyl ether acetate, diethylene glycol monomethyl ether acetate, diethylene glycol monoethyl acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, glycol diacetate, methoxytriglycol acetate, ethyl propionate, n-butyl propionate, i-amyl propionate, diethyl oxalate, di-n-butyl oxalate, methyl lactate, ethyl lactate (EL), n-butyl lactate, n-amyl lactate, diethyl malonate, dimethyl phthalate, diethyl phthalate, propylene glycol 1-monomethyl ether 2-acetate (PGMEA), propylene glycol monoethyl ether acetate, propylene glycol monopropyl ether acetate, N-methylformamide, N,N-dimethylformamide, N,N-diethylformamide, acetamide, N-methylacetamide, N,N-dimethylacetamide, N-methylpropionamide, N-methyl pyrrolidone, dimethyl sulfide, diethyl sulfide, thiophene, tetrahydrothiophene, dimethyl sulfoxide, sulfolane, and 1,3-propane sultone. These solvents can be used alone or in combination of any two or more of these.

The solvent (B) is preferably PGME, PGMEA, EL, nBA, DBE, cyclohexane, 2-heptanone, or any mixture of any of these (more preferably PGME, PGMEA, nBA, DBE or any mixture of any of these; further preferably PGME, PGMEA or any mixture of any of these). The solvent (B) preferably consists of only one or two types of solvents (more preferably only one type). When the solvent (B) consists of two types of solvents, the mass ratio thereof is preferably 5:95 to 95:5 (more preferably 10:90 to 90:10; further preferably 20:80 to 80:20).

It is also an embodiment that the solvent (B) does not substantially contain water in relation to other layers or films. For example, the amount of water in the entire solvent (B) is preferably 0.1 mass % or less (more preferably 0.01 mass % or less; further preferably 0.001 mass % or less). It is also a preferred embodiment that the solvent (B) does not contain water (0 mass %). The solvent (B) preferably consists substantially only of an organic solvent (more preferably consists only of an organic solvent).

The content of the solvent (B) is preferably 60 to 99.9 mass % (more preferably 80 to 99.5 mass %; further preferably 95 to 99.5 mass %; further more preferably 97 to 99.5 mass %) based on the total mass of the resist pattern filling liquid.

### (C) Additive

The filling liquid according to the present invention can further comprise an additive (C). The additive (C) is a surfactant, a crosslinking agent, a polymerization initiator, an acid, a basic compound, a surface smoothing agent, a substrate adhesion enhancer, an antifoaming agent, or any combination of any of these. An example of the acid is acetic acid. The polymerization initiator preferably includes a thermal acid generator (TAG), a thermal base generator (TBG) or a thermal radical generator (more preferably TAG). The additive (C) is preferably a surfactant, a crosslinking agent, a polymerization initiator, or any combination of any of these (more preferably a surfactant, an acid, or any combination of any of these; further preferably a surfactant or an acid; further more preferably an acid). It is also an embodiment of the present invention, by containing a polymerization initiator and a crosslinking agent as additives (C), to cure the film by heating.

The content of the additive (C) (in the case of multiple additives, the sum thereof) is preferably 0 to 10 mass % (more preferably 0 to 8 mass %; further preferably 0.01 to 5 mass %) based on the total mass of the filling liquid. It is also an embodiment of the present invention that the composition according to the invention does not contain additive (C) (0 mass %).

Since the filling film of the present invention does not need to exhibit photosensitivity itself, it requires neither photoacid generator (PAG) nor photobase generator (PBG). One of the features of the present invention is that the filling liquid of the present invention may be substantially free of PAG (D) and PBG (E). Therefore, the content of PAG (D) and/or PBG (E) is preferably 0.00 to 0.5 mass % (more preferably 0.00 to 0.2 mass %; further preferably 0.00 to 0.1 mass %; further more preferably 0.00 to 0.01 mass %) based on the total mass of the filling liquid. It is also a preferred embodiment of the present invention that the filling liquid of the present invention contains neither PAG (D) nor PBG (E) (0.00 mass %).

### <Method for Manufacturing Resist Pattern>

The method for manufacturing a resist pattern according to the present invention comprises the following steps:
(1) applying the filling liquid according to the present invention between the resist patterns formed above the substrate to form a filling film; and
(2) removing the filling film by dry etching using an etchant containing oxygen.

### Step (1)

A resist pattern is formed above a substrate (for example, a silicon/silicon dioxide coated substrate, a silicon nitride substrate, a silicon wafer substrate, a glass substrate, an ITO substrate, etc.), and the filling liquid according to the present invention is applied between the resist patterns.

In the present invention, the “above” includes the case where a layer is formed in contact with and above a substrate and the case where a layer is formed above a substrate with another layer in contact with the layer. For example, a planarization film or a bottom anti-reflective coating can be formed in contact with and above a substrate, and the resist composition can be applied in contact with and above it. A preferred embodiment of the present invention is to apply a resist composition in contact with and above a substrate to form a resist film. The application method is not particularly limited, and examples thereof include methods by coating using a spinner or coater. After application, a filling film is formed by drying or the like. The method for forming a resist pattern is not particularly limited. The resist composition is preferably a metal oxide-containing resist composition, more preferably an organometallic oxide hydroxide-containing resist composition, and those described in JP 2021-73367 A can be used. The resist composition is preferably an EUV metal oxide-containing resist composition, and in one preferred embodiment, it is a negative type resist. The solvent for the metal oxide-containing resist composition is preferably aromatic solvents (for example, xylene and toluene), ether solvents (for example, anisole and tetrahydrofuran), ester solvents (for example, PGMEA, ethyl acetate, nBA and ethyl lactate), alcohol solvents (for example, 4-methyl-2-propanol, 1-butanol, methanol, isopropyl alcohol and 1-propanol), ketone solvents (for example, methyl ethyl ketone and 2-heptanone), or any combination of any of these.

The resist composition is preferably heated to form a resist film after being applied on the substrate. The heating temperature is preferably 75 to 140 °C (more preferably 80 to 130 °C; further preferably 90 to 120 °C). The heating time is preferably 30 to 240 seconds (more preferably 90 to 180 seconds). Heating is preferably performed in air or a nitrogen gas atmosphere. The film thickness of the resist film is preferably 10 to 50 nm (more preferably 15 to 30 nm; further preferably 15 to 25 nm).

The resist film is exposed through a predetermined mask. Although the wavelength of light used for exposure is not particularly limited, it is preferable to perform exposure with light having a wavelength of 13.5 to 248 nm. In particular, KrF excimer laser (wavelength: 248 nm), ArF excimer laser (wavelength: 193 nm), extreme ultraviolet ray (wavelength: 13.5 nm), and the like can be used, and extreme ultraviolet ray is preferable. These wavelengths allow a range of +1%.

After exposure, post exposure bake (PEB) can be performed if necessary. The temperature of PEB is preferably 100 to 200 °C (more preferably 150 to 190 °C), and the heating time is preferably 30 to 240 seconds (more preferably 90 to 180 seconds).

The exposed resist film is developed using a developer to form a resist pattern. Examples of development include alkaline development, organic solvent development, and the like, but organic solvent development is preferred. The developer comprises an organic solvent, and more preferably consists of an organic solvent. In the case of organic solvent development, examples of the developer include hydrocarbon solvents, ether solvents, ester solvents, ketone solvents and alcohol solvents, and ester solvents or ketone solvents are preferred. Exemplified embodiments of the developer include 2-heptanone, nBA and PGMEA. Although not to be bound by theory, since the filling liquid of the present invention is different from the developer for resist patterns, it can be thought that the following effects can be expected. There is a method to develop a resist film and form a resist pattern by using a developer that has similar characteristics to the solvent of the resist composition. In this case, if the developer is present between the resist patterns for a long time, there is a possibility that it may dissolve the resist film or the resist pattern to reduce the film thickness or the thickness of the pattern wall. It can be thought that using different filling liquid and developer, it is possible to shorten the time period during which the developer is present between the resist patterns. Further, although not to be bound by theory, it can be thought that the following phenomenon can occur if the developer and the filling liquid are the same. Since it is desirable to solidify the solid components of the developer after the developer dissolves the soluble portion of the resist film and makes it flow, there is a possibility that the amount of developer used becomes large. Furthermore, the phenomenon in which the soluble portion of the resist film is dissolved and the phenomenon in which the solid components of the developer are solidified occur simultaneously, and there is a possibility that residues derived from the resist film may enter the film derived from the developer. In the case that as a resist pattern, one with high etch resistance is selected, such remaining portions act as a mask that is not designed. It can be thought that using the present invention, these can be avoided.

The filling liquid according to the present invention is applied between resist patterns, and at this time, it is preferably applied to the resist patterns after the developer has been applied, and more preferably, it is used to replace the developer present between the resist patterns.

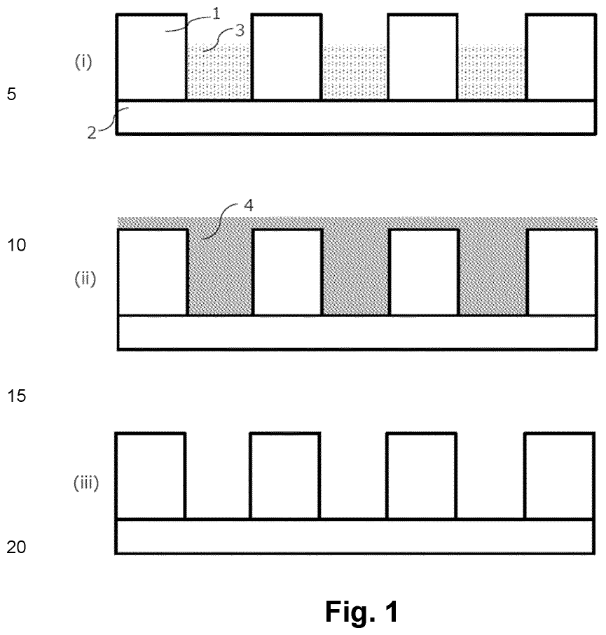

FIG. 1 (i) shows a state in which a resist pattern 1 is formed in contact with and above a substrate 2, and a developer 3 remains between the resist patterns. In this state, the filling liquid according to the present invention can be applied.

After applying the filling liquid, it is dried by spin drying or heating, preferably by heating, to form an filling film. The heating temperature at this time is preferably 75 to 140 °C (more preferably 80 to 130 °C; further preferably 90 to 120 °C). The heating time is preferably 30 to 90 seconds (more preferably 45 to 75 seconds). Heating is preferably performed in air or a nitrogen gas atmosphere.

FIG. 1(ii) shows a state in which the filling liquid is applied to replace the developer, and the filling film 4 is formed. Although FIG. 1(ii) is a drawing in which the resist patterns are completely filled with the filling film, a state in which it is partially filled can be allowed. Even in the case where a filling film is formed only at the bottom between resist patterns, the effect of preventing pattern collapse can be exhibited.

The distance from the surface of the substrate to the surface of the filling film is preferably 20 to 150%, more preferably 40 to 130%, further preferably 60 to 110%, of the distance from the surface of the substrate to the top of the resist pattern. In FIG. 1(ii), since the resist pattern is filled so as to be completely covered by the filling film, the former distance is larger than 100%. It is a suitable embodiment of the present invention that the filling film does not completely cover the resist pattern, the top of the resist pattern wall is not covered with the filling film, and the trench portion is filled with the filling film. In this case, the distance from the surface of the substrate to the surface of the filling film is preferably 30 to 80% (more preferably 30 to 70%; further preferably 40 to 60%) of the distance from the surface of the substrate to the top of the resist pattern.

The distance from the surface of the substrate to the surface of the filling film is measured at the trench portion between the walls of the resist pattern. The midpoint between the walls can be used as a reference point. Similarly, the distance from the surface of the substrate to the top of the resist pattern is determined by measuring the distance in the vertical direction between the trench portion and the top of the resist pattern wall.

The filling film according to the present invention preferably satisfies the following formula:

(total number of atoms in the components constituting the filling film)/((number of carbon atoms in the components constituting the filling film)−(number of oxygen atoms in the components constituting the filling film))=1.0 to 9.0; more preferably 1.2 to 6.0; further preferably 1.4 to 4.0. In the case that the solid components forming the filling film include other components in addition to the polymer (A) (for example, a crosslinking agent), these are also included as constituents of the above formula. It can be calculated by molar ratio.

It is preferable that the filling film according to the present invention has resistance to heating etc. during solvent removal. The glass transition temperature Tg is preferably 100 °C or higher, more preferably 100 to 180 °C, further preferably 120 to 160 °C, further more preferably 120 to 150 °C. Although not to be bound by theory, it can be thought that having such a Tg can prevent solid components (for example, the polymer (A)) from liquefying during heating to remove solvent (B) and collapsing the resist pattern.

### Step (2)

The filling film is removed by dry etching using an etchant containing oxygen. Processing can be performed to remove only the filling film, and then another etching (preferably dry etching) can be performed using the resist pattern as a mask. Removal of the filling film and processing of the substrate using the resist pattern as a mask can be performed by dry etching once or continuously. Preferably, the step (2) and the step (3) are simultaneously performed in one dry etching.

The etching rate of the filling film by dry etching using an etchant containing oxygen is taken as ER_{F}. ER_{F} is preferably ≥0.5 nm/s (more preferably ≥0.8 nm/s).

The etching rate of the resist pattern by dry etching using an etchant containing oxygen is taken as ER_{R}. ER_{R} is preferably ≤0.5 nm/s (more preferably <0.3 nm/s).

ER_{F}/ER_{R} is preferably >1.0 (more preferably >2.5). Although not to be bound by theory, by adopting such etching rate configurations, the resolution of the resist film, itself can be utilized for an etch mask. This point is very different from the reversed resist pattern technology.

Dry etching can be either anisotropic or isotropic, but preferably anisotropic. Etching conditions can be, for example, a substrate temperature of 25 °C, a pressure of 0.67 Pa, and an input power of 100 W.

Regarding the etchant containing oxygen, the oxygen ratio of the etchant in the chamber during plasma generation in dry etching is preferably 10 to 50 volume % (more preferably 20 to 40 volume %; further preferably 25 to 35 volume %).

FIG. 1 (iii) shows a state in which the filling film 4 has been removed by dry etching.

### <Method for Manufacturing Device>

The method for manufacturing a device according to the present invention comprises the following steps:
forming a resist pattern according to the above-mentioned method; and
(3) processing using the resist pattern as a mask.

### Step (3)

The resist pattern is preferably used for processing a resist underlayer or a substrate (more preferably a substrate). In particular, using the resist pattern as a mask, various substrates that become a underlying material can be processed by means of a dry etching method, a wet etching method, an ion implantation method, a metal plating method, or the like. The steps (2) and (3) can be the same step or can be performed continuously.

A underlayer pattern can be formed using the resist pattern as a mask, and the substrate can be processed using the underlayer pattern as a mask. The underlayer and the substrate can be simultaneously processed using the resist pattern as a mask.

Preferably, a step of forming wiring on the processed substrate is further comprised. For these processes, known methods can be applied. Then, if necessary, the substrate is cut into chips, connected to a lead frame, and packaged with resin. In the present invention, this packaged product is referred to as a device. It is preferable that the device is a semiconductor device.

The present invention is explained below with reference to various examples. The embodiments of the present invention are not limited to these examples.

### Preparation of Filling Liquid of Example 1

As the polymer (A), Polymer 1 having the following structure is added to the solvent (B) so that the content thereof is 0.65 mass %. The resultant is stirred for 30 minutes at room temperature, and it is visually confirmed that the polymer (A) has dissolved. Thereafter, the resultant is filtered through a filter with a pore size of 0.2 μm to obtain the filling liquid of Example 1.
Polymer 1: Mw 13,500

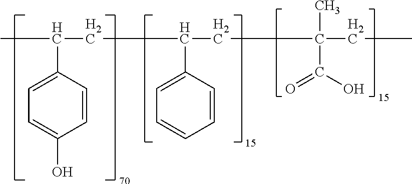

### Preparation of Filling Liquid of Examples 2 to 6

The filling liquids of Examples 2 to 6 are obtained in the same manner as in the above-mentioned preparation except that the components and contents are changed as shown in Table 1.

TABLE 1

| | | | | | | | | Evaluation | |
|---|---|---|---|---|---|---|---|---|---|
| | | | | | | | | of film | Prevention |
| | Polymer (A) | | | Solvent (B) | | Additive (C) | | thickness | of pattern |
| | type | Mw | content | type | content | type | content | reduction | collapse |
| Example 1 | polymer 1 | 13,500 | 0.65 | PGMEA | balance | — | — | A | A |
| | | | mass % | | | | | | |
| Example 2 | polymer 2 | 50,000 | 0.40 | PGMEA | balance | — | — | A | A |
| | | | mass % | | | | | | |
| Example 3 | polymer 3 | 18,000 | 0.55 | PGMEA | balance | — | — | A | A |
| | | | mass % | | | | | | |
| Example 4 | polymer 3 | 18,000 | 0.55 | PGMEA | balance | Acetic | 5 | A | A |
| | | | mass % | | | acid | mass % | | |
| Example 5 | polymer 4 | 9,800 | 0.70 | PGMEA | balance | — | — | A | A |
| | | | mass % | | | | | | |
| Example 6 | polymer 5 | 45,000 | 0.45 | PGMEA | balance | — | — | A | A |
| | | | mass % | | | | | | |

In the table:
Polymer 2: Mw 50,000

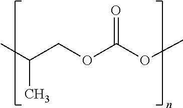

Polymer 3: Mw 18,000

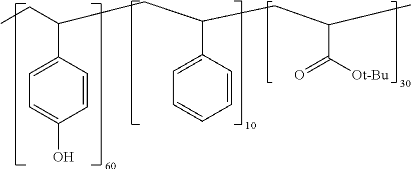

Polymer 4: Mw 9,800

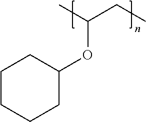

Polymer 5: Mw 45,000

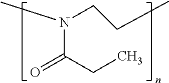

### <Evaluation of Film Thickness Reduction>

As the resist composition, one used in the Example of JP 2020-173360 A for the resist is used. The same also applies hereafter. The resist composition is spin-coated on a 12-inch silicon wafer treated with HMDS, and heated at 100 °C for 2 minutes to form a resist film with a film thickness of 22 nm. Using extreme ultraviolet ray having a wavelength of 13.5 nm, this substrate is subjected to open frame exposure not through a mask. This substrate is subjected to PEB at 170 °C for 2 minutes in an air atmosphere. The film thickness (FT_{R}) of the resist film at this time is measured using an M-2000 ellipsometer (J. A. Woollam). The filling liquids of Examples 1 to 6 are respectively spin-coated on the resist films and heated at 130 °C for 1 minute to form films from the filling liquids. Thereafter, the films respectively formed from the filling liquids are removed using 100% solvent (B) of the filling liquid. Each film thickness (FT_{R′}) of the resist film at this time is measured using an M-2000 ellipsometer. The absolute value of FT_{R}−FT_{R′} is calculated, and when this absolute value is 2 nm or less, it is determined to be A, and when it exceeds 2 nm, it is determined to be B. The results obtained are shown in Table 1.

### Prevention of Pattern Collapse: Example

A resist composition is spin-coated on a 12-inch silicon wafer treated with HMDS, and heated at 100 °C for 2 minutes to form a resist film with a film thickness of 22 nm. Using extreme ultraviolet ray having a wavelength of 13.5 nm, this substrate is exposed so as to form a resist pattern of lines: 15 nm and spaces: 15 nm. This substrate is subjected to PEB at 170 °C for 2 minutes in an air atmosphere. The resist film on the substrate is subjected to paddle development using 2-heptanone for 30 seconds. At this time, 2-heptanone is in the condition that it remains between the resist patterns. Next, while rotating the substrate at 10 rpm, the filling liquid of Example is poured into the center of the substrate to replace 2-heptanone. Thereafter, the substrate is rotated at 1,500 rpm for 30 seconds and heated at 130 °C for 60 seconds to form a filling film. At this time, the resist pattern is in the condition that it is filled with the solid content of the filling liquid. Next, the substrate is placed in a dry etching apparatus and etched for 30 seconds using plasma having an oxygen: nitrogen volume ratio of 3:7. The etching conditions are set to be a substrate temperature of 25 °C, a pressure of 0.67 Pa, and an input power of 100 W. At this time, only the filling film is removed by dry etching, and the resist pattern is hardly removed. Using CG4000 (Hitachi High-Technology), a SEM photograph (0.5 μm×0.5 μm) of the resist pattern is taken, and the presence or absence of pattern collapse is confirmed. When the pattern collapse is not confirmed, the determination is A, and when the pattern collapse is confirmed, the determination is B. The results obtained are shown in Table 1.

### Prevention of Pattern Collapse: Comparative Example

The steps up to the PEB process are carried out in the same manner as the prevention of pattern collapse described above. After the PEB, the resist film on the substrate is subjected to paddle development using 2-heptanone for 30 seconds. Thereafter, the substrate is dried by rotating at 1,500 rpm for 30 seconds. A SEM photograph of the resist pattern thus obtained is taken. In this case, many pattern collapses occur, and it is confirmed that the above-mentioned determination is B.

### <Evaluation of Chemicals Mixing>

The filling liquids of Examples 1 to 6 and 2-heptanone or n-butyl acetate are mixed at a mass ratio (1:9, 5:5, 9:1), and the presence or absence of precipitates after mixing is confirmed using a turbidity meter TR-55 (Kasahara Chemical Instruments) and judged according to the following criteria. The results obtained are shown in Table 2. A is determined to have no precipitate.
A: turbidity is less than 1 degree
B: turbidity is 1 degree or more

TABLE 2

| | Filling liquid: 2-heptanone | | | Filling liquid: n-butyl acetate | | |
|---|---|---|---|---|---|---|
| | 1:9 | 5:5 | 9:1 | 1:9 | 5:5 | 9:1 |
| Example 1 | A | A | A | A | A | A |
| Example 2 | A | A | A | A | A | A |
| Example 3 | A | A | A | A | A | A |
| Example 4 | A | A | A | A | A | A |
| Example 5 | A | A | A | A | A | A |
| Example 6 | A | A | A | A | A | A |

[Explanation of symbols]
1. resist pattern
2. substrate
3. developer
4. filling film

1.-15. (canceled)

16. A resist pattern filling liquid,
wherein
the resist pattern filling liquid forms a resist pattern filling film,
the etching rate of the filling film (ER_{F}) by dry etching using an etchant containing oxygen satisfies ER_{F}≥0.5 nm/s, and
the filling liquid is different from a developer which is applied to a resist film after exposure to form a resist pattern:
optionally, the etching rate of the resist pattern (ER_{R}) by dry etching using an etchant containing oxygen satisfies ER_{R}<0.5 nm/s; or
optionally, ER_{F}/ER_{R}>1.0 is satisfied.

17. The filling liquid according to claim 16, which does not substantially change the film thickness of the resist pattern:
optionally, the film thickness of the resist pattern or resist film (FT_{R}), and the film thickness after applying the filling liquid in contact with and above any of these and removing the filling liquid with the solvent of the filling liquid (FT_{R′}) satisfy the following formula:
(FT_{R}−FT_{R′})/FT_{R}×100=±0 to 10%.

18. The filling liquid according to claim 16, wherein the filling film satisfies the following formula:
(total number of atoms in the components constituting the filling film)/((number of carbon atoms in the components constituting the filling film)−(number of oxygen atoms in the components constituting the filling film))=1.0 to 9.0.

19. The filling liquid according to claim 16, wherein the Tg of the filling film is 100 °C or higher.

20. The filling liquid according to claim 16, comprising a polymer (A) selected from the group consisting of vinyl resin, acrylic resin, polystyrene resin, oxazoline resin, polycarbonate resin, novolak resin, epoxy resin, maleic resin and imide resin:
optionally, the mass average molecular weight (Mw) of the polymer (A) is 2,000 to 100,000.

21. The filling liquid according to claim 16, further comprising a solvent (B), wherein the solvent (B) is water, a hydrocarbon solvent, an ether solvent, an ester solvent, an alcohol solvent, a ketone solvent, or any combination of any of these.

22. The filling liquid according to claim 16, further comprising an additive (C), wherein the additive (C) is a surfactant, a crosslinking agent, a polymerization initiator, an acid, a basic compound, a surface smoothing agent, a substrate adhesion enhancer, an antifoaming agent, or any combination of any of these.

23. The filling liquid according to claim 16, wherein the distance from the surface of the substrate to the surface of the filling film is 20 to 150% of the distance from the surface of the substrate to the top of the resist pattern.

24. The filling liquid according to claim 16, wherein the filling liquid is used to replace the developer present between the resist patterns:
optionally, when the developer and filling liquid are mixed, absorbance does not increase, turbidity does not increase, or solutes derived from at least any of these do not precipitate;
wherein, the resist pattern cleaning solution may or may not be applied between the development and the application of the filling liquid.

25. The filling liquid according to claim 16, wherein the oxygen ratio of the etchant in the chamber during plasma generation in dry etching is 10 to 50 volume %.

26. The filling liquid according to claim 16, wherein the resist pattern is formed from a metal oxide-containing resist composition:
optionally, the metal oxide-containing resist composition is an EUV metal oxide-containing resist composition; or
optionally, the solvent of the metal oxide-containing resist composition is an aromatic solvent, an ether solvent, an ester solvent, an alcohol solvent, a ketone solvent, or any combination of any of these.

27. The filling liquid according to claim 16, wherein the dry etching is anisotropic.

28. The filling liquid according to claim 16, wherein the content of the polymer (A) is 0.05 to 50 mass % based on the total mass of the filling liquid:
optionally, the content of the solvent (B) is 60 to 99.9 mass % based on the total mass of the filling liquid, or
optionally, the content of the additive (C) is 0 to 10 mass % based on the total mass of the filling liquid.

29. A method for manufacturing a resist pattern comprising the following steps:
(1) applying the filling liquid according to claim 16 between the resist patterns formed above the substrate to form a filling film; and
(2) removing the filling film by dry etching using an etchant containing oxygen.

30. A method for manufacturing a device comprising the following steps:
forming a resist pattern according to claim 29; and
(3) processing using the resist pattern as a mask:
optionally, a step of forming wiring on the processed substrate is further comprised; or
optionally, the device is a semiconductor device.
